(19) United States
(12) Patent Application Publication
(10) Pub. No.: US 2026/0026289 A1
(43) Pub. Date: Jan. 22, 2026

(54) SYSTEM AND METHOD OF PROVIDING PRESSURE ON SEMICONDUCTOR DEVICE

(71) Applicant: MI EQUIPMENT (M) SDN. BHD., Bayan Lepas (MY)

(72) Inventor: Pang Yee CHENG, Bayan Lepas (MY)

(21) Appl. No.: 19/273,318

(22) Filed: Jul. 18, 2025

(30) Foreign Application Priority Data
Jul. 18, 2024 (MY) PI2024004205

(51) Int. Cl. H01L 21/67

(52) U.S. Cl. CPC H01L 21/67132

(57) ABSTRACT

The present invention provides a system (101) and method of providing pressure on at least one semiconductor device (103) comprising of at least one press block (105) configured to accommodate at least one press head (107) and at least one actuator (109), suitable to be provided force on at least one sputter target unit (115) placed on a non-elastic platform (111), whereby each press head (107) can provide linear force to their corresponding semiconductor device (103) of said sputter target unit (115) and said press heads (107) are able to provide a predetermined force on said semiconductor device (103) without providing further pressure on said non-elastic platform (111).

### 1. TECHNICAL FIELD OF THE INVENTION

The present invention provides a system and method of providing pressure on at least one semiconductor device comprising of at least one press block configured to accommodate at least one press head and at least one actuator, suitable to be provided force on at least one sputter target unit placed on a non-elastic platform, whereby each press head can provide linear force to their corresponding semiconductor device of said sputter target unit and said press heads are able to provide a predetermined force on said semiconductor device without providing further pressure on said non-elastic platform.

### 2. BACKGROUND OF THE INVENTION

Sputter deposition is a process of physical vapour deposition (PVD) to create a thin layer of film on a particular surface, in some cases the surface of a silicon wafer, semiconductor device, etc. In the case of sputtering semiconductor devices, the sputtering process is generally done using a sputtering machine, whereby a plurality of semiconductor devices is placed on an adhesive tape of a sputter frame and said adhesive tape is placed on a platform, before said semiconductor devices are being pressed or pressured by a mechanism, so that the semiconductor devices are adhered to said adhesive tape before the sputtering process.

Issues start to arise when the plurality of semiconductor devices placed on said adhesive tape have different thickness. In this scenario, certain semiconductor devices will not be pressed by said pressing mechanism because when the pressing mechanism comprises of one single large block and when said pressing mechanism reaches the thickest semiconductor device, the pressing mechanism no longer is able to press on the other semiconductor devices with less thickness due to the distance gap between said pressing mechanism and said semiconductor devices. When said semiconductor devices are not adhering sufficiently to said adhesive tape, backflow of material will happen during the sputtering process, whereby said sputter material will seep into the gap between said semiconductor devices and said adhesive tape.

In some solutions, the platform is made of elastic material, whereby the pressing mechanism can provide further pressure on the group of semiconductor devices, whereby due to the elastic nature of the platform, the semiconductor devices can be further pushed towards said platform to enable all semiconductor devices to receive pressure from said pressing mechanism. This solution was not effective because it is an open loop solution, whereby the user is not able to know the amount of force exerted to each semiconductor device and in the even that excessive force is exerted to certain semiconductor device, said semiconductor device can be damaged.

Another problem arises when the quantity of semiconductor device on said adhesive tape changes. If more semiconductor devices are being pressured by the same force provided by the actuator, the effective force on each semiconductor device will be reduced, therefore affecting the quality of the adherence of said semiconductor on said adhesive tape.

CHEN YIGAO, CN218730820U, disclosed a QFN (Quad Flat No-lead) packaging and heating jig for power supply type products, and particularly relates to the technical field of QFN packaging and heating for power supply type products, whereby the power supply QFN chip frame (3) is provided with a downward pressure resistance heating plate for downward pressure along the vertical upward position (11), and the pressure resistance heating plate (11) which is one single plate is used to provide downward pressure.

Hence, it would be advantageous to alleviate the shortcomings by having a system and method of providing pressure on at least one semiconductor device whereby each press head is able to provide sufficient force to their corresponding semiconductor device even through the platform is non-elastic.

### 3. SUMMARY OF THE INVENTION

Accordingly, it is the primary aim of the present invention to provide a system and method of providing pressure on at least one semiconductor device whereby each press head is able to provide sufficient force to their corresponding semiconductor device even though said semiconductor devices on the same adhesive tape are having different thickness, said sufficient force is such that no backflow is observed during and after the sputtering process.

It is yet another objective of the present invention to provide a system and method of providing pressure on at least one semiconductor device which can be used with a non-elastic platform accommodating the sputter target unit, because no force absorption is observed at the side of the semiconductor device engaging with said platform.

It is yet another objective of the present invention to provide a system and method of providing pressure on at least one semiconductor device which allows each press head to provide predetermined controlled force on each individual corresponding semiconductor device.

It is yet another objective of the present invention to provide a system and method of providing pressure on at least one semiconductor device which allows the force being applied by each press head on their corresponding semiconductor device to be measured.

Additional objects of the invention will become apparent with an understanding of the following detailed description of the invention or upon employment of the invention in actual practice.

According to the preferred embodiment of the present invention the following is provided:

A system for providing pressure on at least one semiconductor device, comprising:
at least one press block configured to accommodate at least one press head;
at least one actuator configured to engage with said press block and provide linear force towards said press block to move linearly towards at least one platform;
characterized in that
said platform is configured to accommodate at least one sputter target unit; wherein said sputter target unit comprises of at least one adhesive tape with its adhesive side facing said press block; said sputter target unit further comprises of at least one tape holding mechanism at said adhesive tape's periphery configured to hold said adhesive tape in flat position; said sputter target unit further comprises of at least one semiconductor device being placed on said adhesive side of said adhesive tape;
wherein said sputter target unit is placed between said platform and said press block;
each said press head comprises of ALO compression device; each press head is configured to be aligned with its corresponding semiconductor device; wherein each press head is configured to provide predetermined force on its corresponding semiconductor device upon said press block being forced by said actuator;
the surface of said platform accommodating said sputter target unit is non-elastic;
wherein said system further comprises of at least one data processing means configured to instruct said actuator to force said press block to provide said linear force, instruct said press head to provide said predetermined force or combination thereof;
wherein said system further comprises of at least one force measurement mechanism configured to measure exertion force applied to each compression device when said compression device is being pushed by said press head for at least one compression distance against said force measurement mechanism; and feedback to said data processing means to calculate and determine said predetermined force to be applied on said semiconductor devices.

In another embodiment of the invention there is provided:

A method of providing pressure on at least one semiconductor device, comprising the steps of:
(i) measuring at least one exertion force of at least one compression device attached to its press head using at least one force measurement mechanism when said compression device is being pushed by said press head for at least one compression distance against said force measurement mechanism; to determine the correlation between said compression distance of said compression device and said exertion force provided by said compression device; wherein said press head is within a press block; wherein an actuator is configured to move said press block towards said force measurement mechanism, causing said compression device to be compressed when said press head is against said force measurement mechanism;
(ii) determining a predetermined exertion force to be applied to at least one semiconductor device by their corresponding press head;
(iii) calculating the total distance needed to be travelled by each of said press head to achieve said predetermined exertion force in step (ii); based on said predetermined exertion force in step (ii) and correlation between said exertion force and said compression distance for said compression device in step (i); wherein said total distance is the sum of the initial distance between said press head and its corresponding semiconductor device; and said compression distance of said compression device;
(iv) calculating the average total distance of all the compression device in the same press block;
(v) moving linearly of said press block towards at least one platform; whereby said platform is configured to accommodate at least one sputter target unit; wherein said sputter target unit comprises of at least one adhesive tape with its adhesive side facing said press block; said sputter target unit further comprises of at least one tape holding mechanism at said adhesive tape's periphery configured to hold said adhesive tape in flat position; said sputter target unit further comprises of at least one semiconductor device being placed on said adhesive side of said adhesive tape; wherein said sputter target unit is placed between said platform and said press block; wherein each press head is configured to be aligned with said semiconductor device.

### 4. BRIEF DESCRIPTION OF THE DRAWINGS

Other aspect of the present invention and their advantages will be discerned after studying the Detailed Description in conjunction with the accompanying drawings in which:

FIG. 1 illustrates a side view of the system of the present invention before the actuator provides force to the press block.

FIG. 2 illustrates a side view of the system of the present invention after the actuator provides force to the press block, until any one of the press head is in touch with the thickest semiconductor device on the adhesive tape.

FIG. 3 illustrates a side view of the system of the present invention after the actuator provides further force to the press block, all press heads are touching their corresponding semiconductor device.

FIG. 4 illustrates a flow chart depicting the method of the present invention.

FIG. 5A illustrates a side view of the system of the present invention when performing step (i) of the method of the present invention whereby the first press head is positioned aligned with the force measurement mechanism while FIG. 5B illustrates a side view of the system of the present invention when performing step (i) of the method of the present invention whereby the actuator pushes the press block to perform over-compression of the first compression device on said first press head so that the exertion force of said first compression device can be measurement by said force measurement device.

FIGS. 6A, 6B, 6C and 6D are closed-up side views showing the first press head being aligned with the force measurement device, whereby FIG. 6A is when the first press head touches the force measurement device, FIG. 6B is when the first compression device on said first press head is over-compressed by a distance of X1, FIG. 6C is when the first compression device on said first press head is over-compressed by a distance of X2, and FIG. 6D is when the first compression device on said first press head is over-compressed by a distance of X3.

FIG. 7A illustrates a side view of the system of the present invention when performing step (i) of the method of the present invention whereby the second press head is positioned aligned with the force measurement mechanism while FIG. 7B illustrates a side view of the system of the present invention when performing step (i) of the method of the present invention whereby the actuator pushes the press block to perform over-compression of the second compression device on said second press head so that the exertion force of said second compression device can be measurement by said force measurement device.

FIGS. 8A, 8B, 8C and 8D are closed-up side views showing the second press head being aligned with the force measurement device, whereby FIG. 8A is when the second press head touches the force measurement device, FIG. 8B is when the second compression device on said second press head is over-compressed by a distance of Y1, FIG. 8C is when the second compression device on said second press head is over-compressed by a distance of Y2, and FIG. 8D is when the second compression device on said second press head is over-compressed by a distance of Y3.

### 5. DETAILED DESCRIPTION OF THE INVENTION

In the following detailed description, numerous specific details are set forth in order to provide a thorough understanding of the invention. However, it will be understood by the person having ordinary skill in the art that the invention may be practised without these specific details. In other instances, well known methods, procedures and/or components have not been described in detail so as not to obscure the invention.

The invention will be more clearly understood from the following description of the embodiments thereof, given by way of example only with reference to the accompanying drawings, which are not drawn to scale.

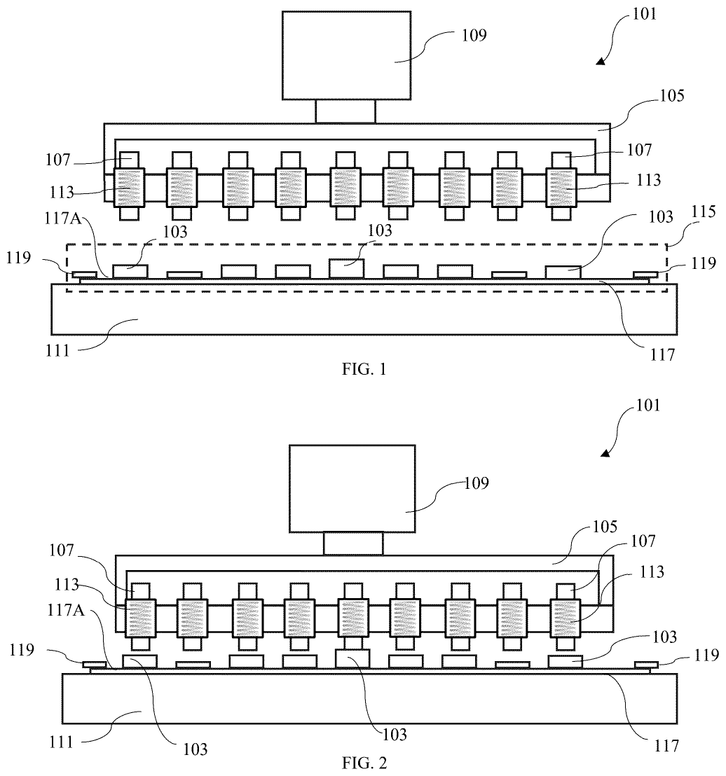

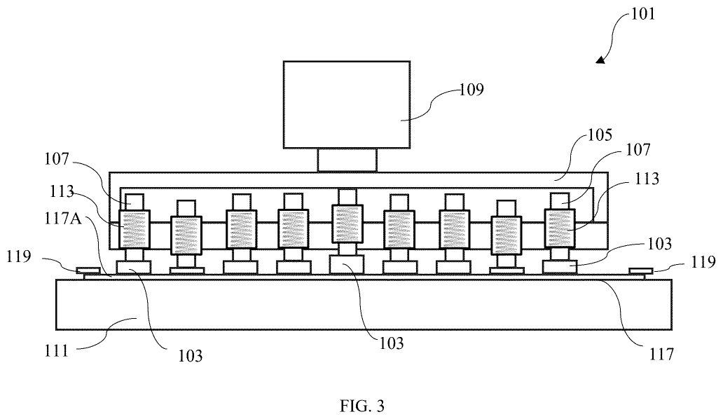

The invention presents a system (101) for providing pressure on at least one semiconductor device (103), as shown in FIG. 1, comprising at least one press block (105) configured to accommodate at least one press head (107) and at least one actuator (109) configured to engage with said press block (105) and provide linear force towards said press block to move linearly towards at least one platform (111). The actuator (109) can be a press motor.

The platform (111) is configured to accommodate at least one sputter target unit (115); wherein said sputter target unit (115) comprises of at least one adhesive tape (117) with its adhesive side (117A) facing said press block (105); said sputter target unit (115) further comprises of at least one tape holding mechanism (119) at said adhesive tape's (117) periphery configured to hold said adhesive tape in flat position; said sputter target unit (115) further comprises of at least one semiconductor device (103) being placed on said adhesive side (117A) of said adhesive tape (117). A plurality of said semiconductor devices (103) are placed at a predetermined distance between themselves. The sputter target unit (115) is placed on said platform (111); and between said platform (111) and said press block (105). The surface of said platform (111) accommodating said sputter target unit (115) is non-elastic. The semiconductor device (103) can be a QFN device. The tape holding mechanism (119) can be a fixture, jig or sputter frame.

Each said press head (107) comprises of at least one compression device (113); each press head (107) is configured to be aligned with its corresponding semiconductor device (103); wherein each press head (107) is configured to provide predetermined force on its corresponding semiconductor device (103) upon said press block (105) being forced by said actuator (109). The predetermined force provided by each press head (107) is inversely proportional with the thickness of its corresponding semiconductor device (103).

The system 101 further comprises of at least one data processing means configured to instruct said press block (105) to provide said linear force, instruct said press head (107) to provide said predetermined force or combination thereof. The predetermined force provided by each press head (107) towards its corresponding semiconductor device (103) can be controlled by said data processing means. In view that a predetermined force is applied by said press head (107) on its corresponding semiconductor device (103) and said platform (111) is non-elastic, no force is being absorbed at the side of the semiconductor device (103) in contact with said adhesive tape (117).

The system (101) further comprises of at least one force measurement mechanism (501) such as a load cell configured to measure exertion force applied to each compression device (113) when said compression device (113) is being pushed by said press head (107) for at least one compression distance against said force measurement mechanism (501); and feedback to said data processing means to calculate and determine said predetermined force to be applied on said semiconductor devices (103).

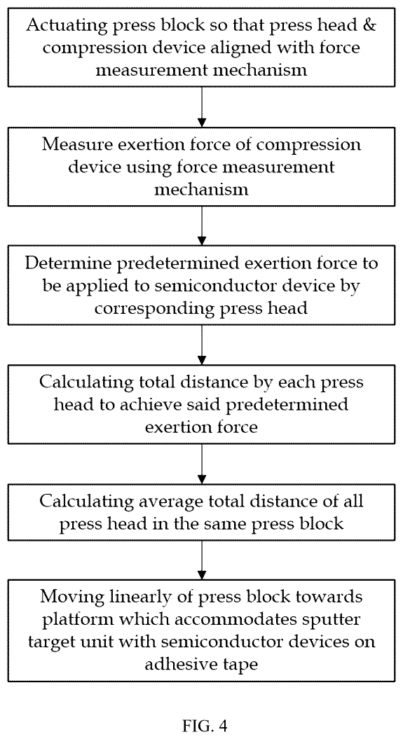

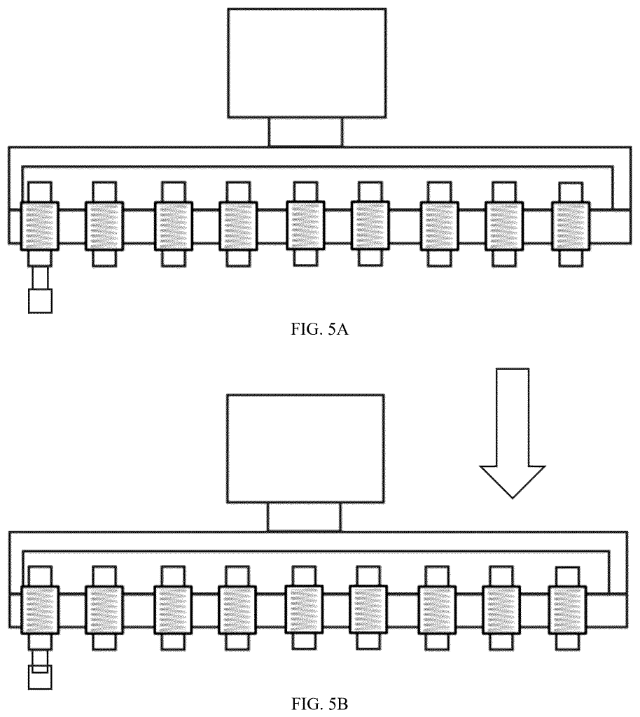

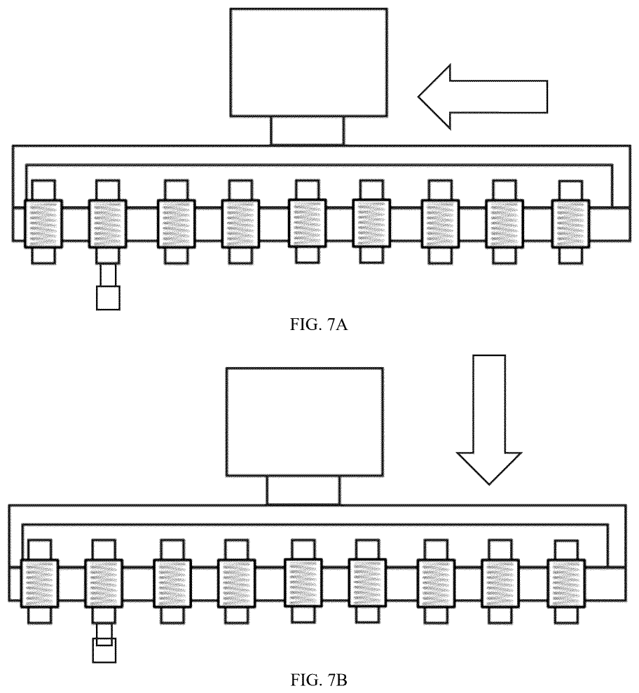

The present invention is also a method of providing pressure on at least one semiconductor device (103), as shown in FIG. 4, comprising the following steps. Before step (i), as shown in FIG. 5A and FIG. 7A, at least one press block (105) is actuated such that at least one press head (107) and its corresponding compression device (113) is aligned to at least one force measurement mechanism (501).

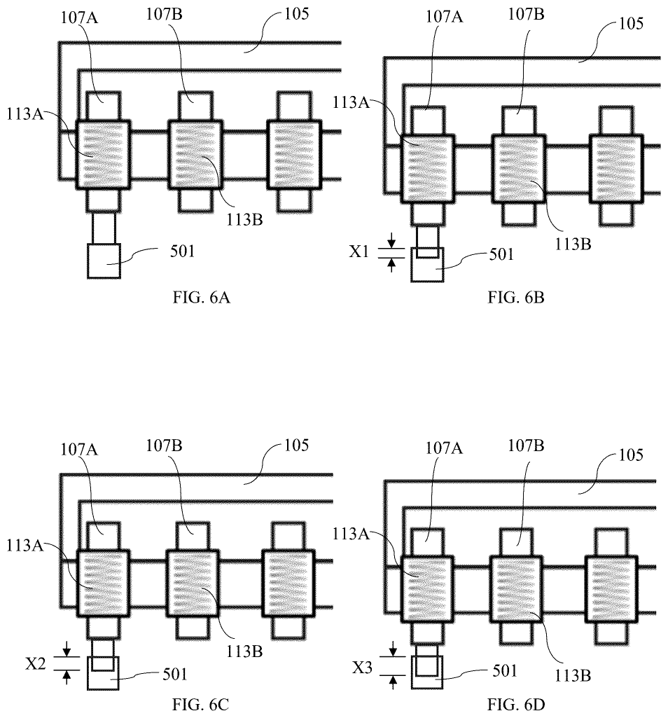

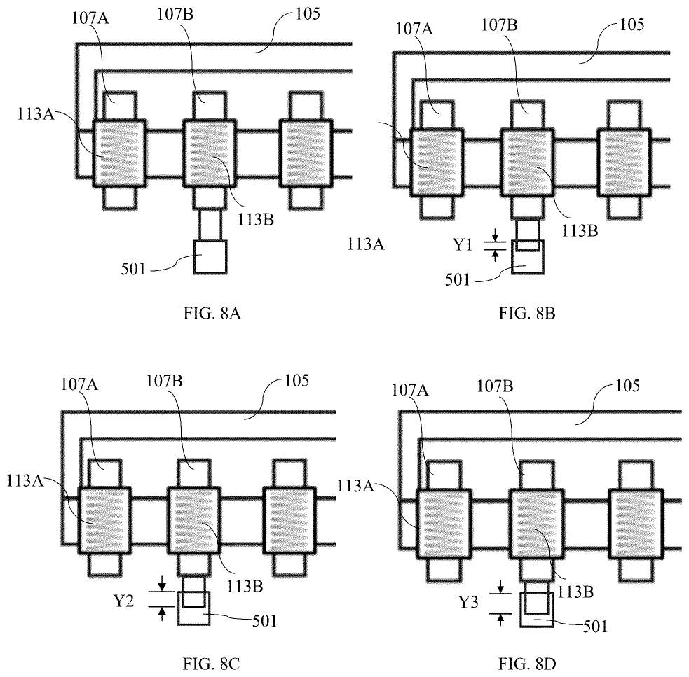

In step (i), at least one exertion force of at least one compression device (113) attached to its press head (107) is measured using at least one force measurement mechanism (501) when said compression device (113) is being pushed by said press head (107) for at least one compression distance against said force measurement mechanism (501), as shown in FIG. 5B and FIG. 7B. This action is to determine the correlation between said compression distance of said compression device (113) and said exertion force provided by said compression device (113). The press head (107) is within a press block (105). Step (i) is important because the compression characteristics of each compression device (113) in said press block may be different. At least one actuator (109) is configured to move said press block (105) towards said force measurement mechanism (501), causing said compression device (113) to be compressed when said press head (107) is against said force measurement mechanism (501). As shown in FIG. 6A to 6D, in one of the examples of application, the first compression device (113A) is being over-compressed by a plurality of compression distances (for example 100 micron (X1), 200 micron (X2), 300 micron (X3), 400 micron and 500 micron) while the plurality of corresponding exertion forces is being measured and collected (for example 100 g, 150 g, 200 g, 250 g and 300 g). Thereafter, as shown in FIG. 8A to 8D, the second compression device (113B) is being over-compressed by a plurality of compression distances (for example 100 micron (Y1), 200 micron (Y2), 300 micron (Y3), 400 micron and 500 micron) while the plurality of corresponding exertion forces is being measured and collected (for example 100 g, 200 g, 300 g, 400 g and 500 g).

In Step (ii), a predetermined exertion force to be applied to at least one semiconductor device (103) by their corresponding press head (107) is determined. For example, the user may want to set the predetermined exertion force to be 100 g of over-compression to be applied to all semiconductor devices (103) that are being placed on at least one adhesive tape (117) such that said 100 g over-compression to said semiconductor devices (103) provides sufficient attachment between said semiconductor device (103) and said adhesive tape (117) to avoid back-flow during a sputtering process and at the same time not damaging said semiconductor device (103).

In Step (iii), the total distance needed to be travelled by each of said press head (107) to achieve said predetermined exertion force in step (ii) is calculated; based on said predetermined exertion force in step (ii) and correlation between said exertion force and said compression distance for said compression device (113) in step (i). The total distance is the sum of the initial distance between said press head (107) and its corresponding semiconductor device (103); and said compression distance of said compression device (113). For example, if the initial distance between the first press head (107A) and the first semiconductor device is 100 micron and a predetermined exertion force of 300 g is needed, while from step (i), 500 micron of over-compression is needed to provide 300 g of exertion force, the total distance needed for the first press head is the sum of 100 micron and 500 microns, which is 600 microns. For the second press head (107B), if the initial distance between the first press head (107A) and the first semiconductor device is 200 micron and a predetermined exertion force of 300 g is needed, while from step (i) 300 micron of over-compression is needed to provide 300 g of exertion force, the total distance needed for the first press head is the sum of 200 micron and 300 microns, which is 500 microns. The total distances for each of the press heads (107) in said press block (105) are determined.

In step (iv), said press block (105) is moved linearly towards at least one platform (111); whereby said platform (111) is configured to accommodate at least one sputter target unit (115). The sputter target unit (115) comprises of at least one adhesive tape (117) with its adhesive side (117A) facing said press block (105). The sputter target unit (115) further comprises of at least one tape holding mechanism (119) at said adhesive tape's (117) periphery configured to hold said adhesive tape (117) in flat position. The sputter target unit (115) further comprises of at least one said semiconductor device (103) being placed on said adhesive side (117A) of said adhesive tape (117). The sputter target unit (115) is placed between said platform (111) and said press block (105); wherein each press head (107) is configured to be aligned with said semiconductor device (103).

The method of providing pressure on at least one semiconductor device (103) further comprises of the step of calculating the average total distance of all the press head (107) in the same press block (105) between step (iii) and step (iv). The total distances are averaged because all the press heads are controlled by the same press block, and hence the actuator (109) is able to only provide one total distance for all the press heads (107) in the same press block (105). The averaging step may be eliminated if each press head (107) is actuated by their respective actuators (109). Using the example above, if the total distance for the first press head is 600 microns and for the total distance for the second press head is 500 microns and assuming that there are only two press heads in the same press block (105), the average total distance is 550 microns.

While the present invention has been shown and described herein in what are considered to be the preferred embodiments thereof, illustrating the results and advantages over the prior art obtained through the present invention, the invention is not limited to those specific embodiments. Thus, the forms of the invention shown and described herein are to be taken as illustrative only and other embodiments may be selected without departing from the scope of the present invention, as set forth in the claims appended hereto.

What is claimed is:

1. A system (101) for providing pressure on at least one semiconductor device (103), comprising:
at least one press block (105) configured to accommodate at least one press head (107);
at least one actuator (109) configured to engage with said press block (105) and provide linear force towards said press block (105) to move linearly towards at least one platform (111);
characterized in that
said platform (111) is configured to accommodate at least one sputter target unit (115); wherein said sputter target unit (115) comprises of at least one adhesive tape (117) with its adhesive side (117A) facing said press block (105); said sputter target unit (115) further comprises of at least one tape holding mechanism (119) at said adhesive tape's (117) periphery configured to hold said adhesive tape (117) in flat position; said sputter target unit (115) further comprises of at least one semiconductor device (103) being placed on said adhesive side (117A) of said adhesive tape (117);
wherein said sputter target unit (115) is placed between said platform (111) and said press block (105);
each said press head (107) comprises of at least one compression device (113);
each press head (107) is configured to be aligned with its corresponding semiconductor device (103); wherein each press head (107) is configured to provide predetermined force on its corresponding semiconductor device (103) upon said press block (105) being forced by said actuator (109);
the surface of said platform (111) accommodating said sputter target unit (115) is non-elastic;
wherein said system (101) further comprises of at least one data processing means configured to instruct said actuator (109) to force said press block (105) to provide said linear force,
wherein said system (101) further comprises of at least one force measurement mechanism (501) configured to measure exertion force applied to each compression device (113) when said compression device (113) is being pushed by said press head (107) for at least one compression distance against said force measurement mechanism (501); and feedback to said data processing means to calculate and determine said predetermined force to be applied on said semiconductor devices (103).

2. The system (101) for providing pressure on at least one semiconductor device (103) as claimed in claim 1, wherein said actuator (109) is press motor.

3. The system (101) for providing pressure on at least one semiconductor device (103) as claimed in claim 1, wherein a plurality of said semiconductor devices (103) are placed at a predetermined distance between themselves.

4. The system (101) for providing pressure on at least one semiconductor device (103) as claimed in claim 1, wherein said predetermined force provided by each press head (107) is inversely proportional with the thickness of its corresponding semiconductor device (103).

5. The system (101) for providing pressure on at least one semiconductor device (103) as claimed in claim 1, wherein said adhesive tape (117) is mylar tape, PU tape or any other adhesive tape suitable to be used with sputtering process.

6. The system (101) for providing pressure on at least one semiconductor device (103) as claimed in claim 1, wherein said force measurement mechanism is load cell.

7. A method of providing pressure on at least one semiconductor device (103), comprising the steps of:
(i) measuring at least one exertion force of at least one compression device (113) attached to its press head (107) using at least one force measurement mechanism (501) when said compression device (113) is being pushed by said press head (107) for at least one compression distance against said force measurement mechanism (501); to determine the correlation between said compression distance of said compression device (113) and said exertion force provided by said compression device (113); wherein said press head (107) is within a press block (105); wherein an actuator (109) is configured to move said press block (105) towards said force measurement mechanism (501), causing said compression device (113) to be compressed when said press head (107) is against said force measurement mechanism (501);
(ii) determining a predetermined exertion force to be applied to at least one semiconductor device (103) by their corresponding press head (107);
(iii) calculating the total distance needed to be travelled by each of said press head (107) to achieve said predetermined exertion force in step (ii); based on said predetermined exertion force in step (ii) and correlation between said exertion force and said compression distance for said compression device (113) in step (i); wherein said total distance is the sum of an initial distance between said press head (107) and its corresponding semiconductor device (103); and said compression distance of said compression device (113);
(iv) moving linearly of said press block (105) towards at least one platform (111); whereby said platform (111) is configured to accommodate at least one sputter target unit (115); wherein said sputter target unit (115) comprises of at least one adhesive tape (117) with its adhesive side (117A) facing said press block (105); said sputter target unit (115) further comprises of at least one tape holding mechanism (119) at said adhesive tape's (117) periphery configured to hold said adhesive tape (117) in flat position; said sputter target unit (115) further comprises of at least one semiconductor device (103) being placed on said adhesive side (117A) of said adhesive tape (117); wherein said sputter target unit (115) is placed between said platform (111) and said press block (105); wherein each press head (107) is configured to be aligned with said semiconductor device (103).

8. The method of providing pressure on at least one semiconductor device (103) as claimed in claim 7, further comprising of the step of calculating the average total distance of all the press head (107) in the same press block (105) between step (iii) and (iv).

9. The method of providing pressure on at least one semiconductor device (103) as claimed in claim 7, wherein said press block (105) is actuated such that at least one press head (107) and its corresponding compression device (113) is aligned to said force measurement mechanism (501), before step (i).
